(19) United States
(12) Patent Application Publication
(10) Pub. No.: US 2026/0052739 A1
(43) Pub. Date: Feb. 19, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chi-Hsuan Tang, Kaohsiung city (TW); Tzu-Wei Liao, Pingtung County (TW); Shi-Xiong Lin, Yilan County (TW); Chung-Ting Huang, Kaohsiung City (TW); Chia-Min Huang, Taipei City (TW); Yu-Tzu Wu, Chiayi City (TW); Chun-Jen Chen, Tainan City (TW); Ming-Hua Chang, Tainan City (TW)

(73) Assignee: UNITED MICROELECTRONICS CORP., Hsin-Chu City (TW)

(21) Appl. No.: 18/890,777

(22) Filed: Sep. 20, 2024

(30) Foreign Application Priority Data
Aug. 16, 2024 (TW) 113130804

(51) Int. Cl. H01L 29/66; H01L 21/02; H01L 21/3065; H01L 29/08; H01L 29/78

(52) U.S. Cl. CPC H10D 62/021; H01L 21/0262; H01L 21/3065; H10D 30/601; H10D 62/151; H10D 30/0227

(57) ABSTRACT

A semiconductor device includes a gate structure, two recesses and two epitaxial layers. The gate structure is disposed on a substrate. The two recesses are disposed in the substrate and at two sides of the gate structure. Each of the recesses includes a first inclined surface, a second inclined surface and a third inclined surface connected sequentially from bottom to top. The first inclined surface and the second inclined surface define a first tip structure therebetween. The second inclined surface and the third inclined surface define a second tip structure therebetween. The two epitaxial layers are respectively disposed in the two recesses.

### BACKGROUND OF THE INVENTION

### 1. Field of the Invention

The present disclosure relates to the field of semiconductor devices, and more particularly, to a semiconductor device which is beneficial to improve the channel stress and a method for fabricating the same.

### 2. Description of the Prior Art

In advanced semiconductor processes, the strained-silicon technology has been developed to increase the drive current of transistors. The principle of the strained-silicon technology is to introduce strain in the silicon lattice of the gate channel to increase the carrier mobility. Thereby, the drive current is increased, and the operation of the transistor is speeded up.

One of the current methods to introduce strain in the silicon lattice of the gate channel is to combine the selective epitaxial growth (SEG) technology, in which two recesses are firstly formed in the substrate and at two sides of the gate structure, and then the selective epitaxial growth process is performed to form two epitaxial layers respectively in the two recesses. The two epitaxial layers with a lattice arrangement identical to that of the substrate and a lattice constant different from that of the substrate are served as source/drain regions, and the two epitaxial layers can provide stress to the lattice close to the channel region to increase the carrier mobility.

As the desired operating speed of transistors continues to increase, how to improve the structure of semiconductor devices to increase the carrier mobility in the channel region has become a goal of the relevant industry.

### SUMMARY OF THE INVENTION

According to an embodiment of the present disclosure, a semiconductor device includes a gate structure, two recesses and two epitaxial layers. The gate structure is disposed on a substrate. The two recesses are disposed in the substrate and at two sides of the gate structure. Each of the recesses includes a first inclined surface, a second inclined surface and a third inclined surface connected sequentially from bottom to top. The first inclined surface and the second inclined surface define a first tip structure therebetween. The second inclined surface and the third inclined surface define a second tip structure therebetween. The two epitaxial layers are respectively disposed in the two recesses.

According to another embodiment of the present disclosure, a method for fabricating a semiconductor device includes steps as follows. A gate structure is formed on a substrate. Two recesses are formed in the substrate and at two sides of the gate structure. Each of the recesses includes a first inclined surface, a second inclined surface and a third inclined surface connected sequentially from bottom to top. The first inclined surface and the second inclined surface define a first tip structure therebetween. The second inclined surface and the third inclined surface define a second tip structure therebetween. Two epitaxial layers are formed respectively in the two recesses.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4 and FIG. 5 are schematic cross-sectional views showing steps of a method for fabricating a semiconductor device according to an embodiment of the present disclosure.

FIG. 6 is a schematic cross-sectional view showing a semi-finished semiconductor device according to another embodiment of the present disclosure.

FIG. 7 is a schematic cross-sectional view showing a semiconductor device according to the another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

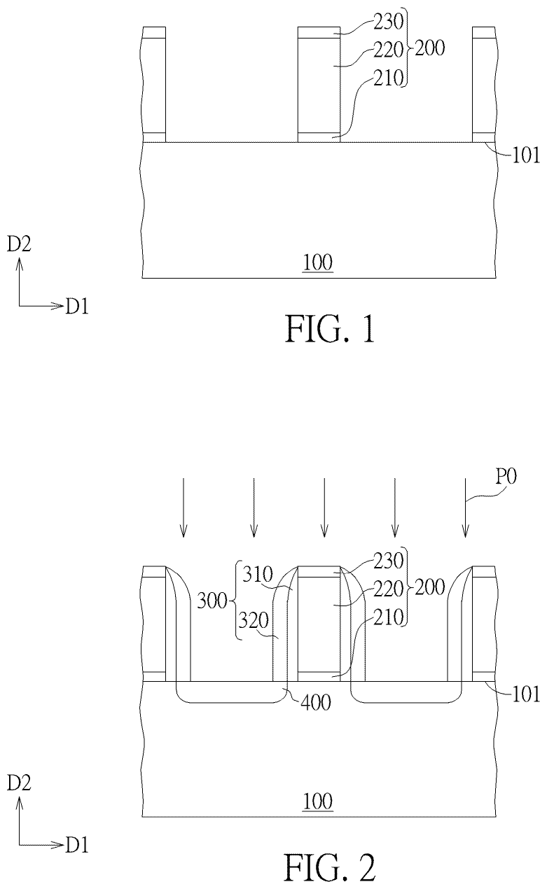

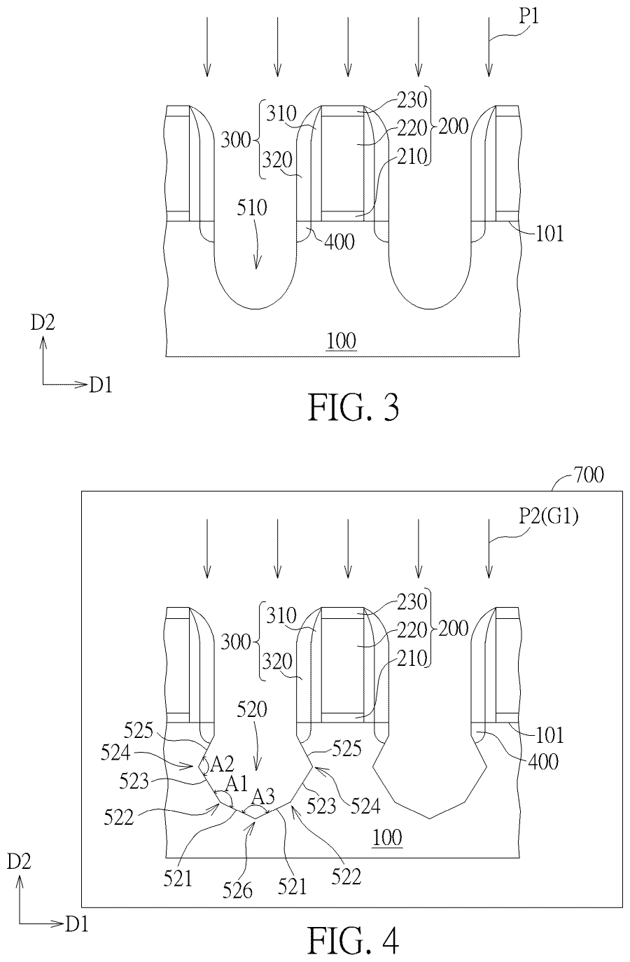

Please refer to FIG. 1 to FIG. 5, which are schematic cross-sectional views showing steps of a method for fabricating a semiconductor device according to an embodiment of the present disclosure. In the embodiment, the semiconductor device 1 (see FIG. 5) is exemplary a PMOS transistor for explanation. As shown in FIG. 1, a gate structure 200 is firstly formed on a substrate 100. The substrate 100 may be a silicon substrate, an epitaxial silicon substrate, a silicon carbide substrate or a silicon on insulator (SOI) substrate. The substrate 100 may include a well region (not shown). For example, the well region may be formed by an ion implantation process (not shown). The dopant of the well region may be adjusted depending on the subsequently formed semiconductor device 1 being applied to an NMOS transistor or a PMOS transistor. In the embodiment, the semiconductor device 1 is exemplary a PMOS transistor. Therefore, the well region is an N-type well region, and the well region may be doped with N-type dopants, such as arsenic, phosphorus, etc.

The gate structure 200 includes a gate dielectric layer 210, a gate material layer 220 and a mask layer 230 from bottom to top. In the embodiment, the formation of the gate structure 200 may be accomplished by a gate first process, a high-k first approach of a gate last process, or a high-k last approach of a gate last process. In the embodiment, the gate structure 200 is exemplary formed by a high-k last approach. A gate dielectric material, a gate material and a mask material may be formed sequentially on the substrate 100 by a deposition process, and a pattern transfer process may be performed by using a patterned photoresist (not shown) as a mask to remove a portion of the mask material, a portion of the gate material and a portion of the gate dielectric material by a single etching process or multiple etching processes. Next, the patterned photoresist is removed, and the gate structure 200 including the gate dielectric layer 210, the gate material layer 220 and the mask layer 230 is formed on a top surface 101 of the substrate 100. The material of the gate dielectric layer 210 may include, but is not limited to, oxides and/or nitrides. The oxide, for example, may include silicon dioxide (SiO₂). The nitride, for example, may include silicon nitride (SiN). The material of the gate material layer 220 may include, but is not limited to, non-metallic conductive materials, such as polycrystalline silicon. The material of the mask layer 230 may include, but is not limited to, silicon dioxide (SiO₂), silicon nitride (SiN), silicon carbide (SiC) and/or silicon oxynitride (SiON).

In addition, although the embodiment takes a planar transistor as an example, in other modified embodiments, the method for fabricating the semiconductor device of the present disclosure may also be applied to a non-planar transistor, such as a transistor with a fin-shaped structure. In this case, the portion of the substrate 100 shown in FIG. 1 may represent the fin-shaped structure formed on the substrate 100.

Next, as shown in FIG. 2, a spacer 300 may be optionally formed to surround the gate structure 200. First, a first spacer 310 is formed to surround the gate structure 200. The first spacer 310 may be, for example, an offset spacer. The material of the first spacer 310 may include, for example, oxides such as silicon dioxide (SiO₂). Next, an ion implantation process P0 is performed to form two lightly doped drain regions 400 in the substrate 100 and at two sides of the gate structure 200. The conductivity types of the two lightly doped drain regions 400 are identical to each other, and are different from the conductivity type of the well region. In the embodiment, the well region is an N-type well region, and the conductivity types of the two lightly doped drain regions 400 are P-type. Therefore, in the ion implantation process P0, P-type dopants are implanted into the substrate 100. The P-type dopants may include, for example, boron (B), aluminum (Al), gallium (Ga), or indium (In). Next, a second spacer 320 is formed to surround the gate structure 200. The material of the second spacer 320 may include nitrides, such as silicon nitride, silicon oxynitride or silicon carbonitride. In FIG. 2, the spacer 300 is a double-layer structure including the first spacer 310 and the second spacer 320. However, it is only exemplary. The number of the layers of the spacer 300 and the material of each layer of the spacer 300 may be adjusted according to actual needs.

Next, two recesses 520 (see FIG. 4) are formed in the substrate 100 and at the two sides of the gate structure 200, which may include steps as follows. First, as shown in FIG. 3, two initial recesses 510 are formed in the substrate 100 and at the two sides of the gate structure 200. Each of the two initial recesses 510 includes a U-shaped profile. For example, a dry etching process Pl may be performed, in which the gate structure 200 and the spacer 300 are served as the etching mask, and a single dry etching process P1 or multiple dry etching processes P1 are performed along the spacer 300 downwardly to remove a portion of the substrate 100 to form the two initial recesses 510 in the substrate 100 and at the two sides of the gate structure 200. The two initial recesses 510 are arranged along the horizontal direction D1.

Next, as shown in FIG. 4, another dry etching process P2 may be performed to convert the two initial recesses 510 into the two recesses 520. Each of the recesses 520 includes a first inclined surface 521, a second inclined surface 523 and a third inclined surface 525 connected sequentially from bottom to top. The first inclined surface 521 and the second inclined surface 523 define a first tip structure 522 therebetween, and the second inclined surface 523 and the third inclined surface 525 define a second tip structure 524 therebetween. Thereby, each of the recesses 520 includes at least two tip structures, which is beneficial for improving the strain in the crystal lattice adjacent to the channel region, so as to increase the carrier mobility in the channel region. Accordingly, the operating speed of the semiconductor device 1 formed later can be enhanced.

Specifically, the dry etching process P2 may be performed at a temperature ranging from 800° C. to 900° C. The dry etching process P2 may be performed for 50 seconds to 70 seconds. The dry etching process P2 may include introducing a first etching gas G1. The first etching gas G1 may include hydrogen chloride (HCl), and a flow rate of the first etching gas G1 may range from 50 sccm (Standard Cubic Centimeter per Minute) to 250 sccm.

Next, as shown in FIG. 5, two buffer layers 610 may be optionally formed in the two recesses 520, respectively. Next, two first epitaxial layers 620 may be respectively formed in the two recesses 520, in which the two first epitaxial layers 620 are respectively disposed on the two buffer layers 610. Next, two second epitaxial layers 630 may be respectively formed on the two first epitaxial layers 620. Next, two cap layers 640 may be respectively formed on the two second epitaxial layers 630. The two cap layers 640 completely cover the two second epitaxial layers 630. Thereby, the fabrication of the semiconductor device 1 is completed. Specifically, a selective epitaxial growth process P3 may be performed. For example, a chemical vapor deposition system may be used, and a second etching gas G2 and an epitaxial material gas G3 may be respectively introduced into the chemical vapor deposition system to form the two buffer layers 610, the two first epitaxial layers 620, the two second epitaxial layers 630 and the two cap layers 640 in sequence.

According to an embodiment of the present disclosure, the materials of the buffer layer 610, the first epitaxial layer 620 and the second epitaxial layer 630 may all include silicon germanium (SiGe). The material of the cap layer 640 may include silicon. A concentration of germanium in the buffer layer 610 may be substantially fixed. A concentration of germanium in the first epitaxial layer 620 may be substantially fixed, and the concentration of germanium in the first epitaxial layer 620 may be greater than the concentration of germanium in the buffer layer 610. A concentration of germanium in the second epitaxial layer 630 may change in gradient along the vertical direction D2 from bottom to top. For example, the concentration of germanium in the second epitaxial layer 630 may decrease gradually from bottom to top along the vertical direction D2, or may change gradually from a concentration identical to that in the first epitaxial layer 620 to zero from bottom to top along the vertical direction D2. The material of the cap layer 640 does not include germanium (that is, the concentration of germanium in the cap layer 640 is zero). The aforementioned vertical direction D2, for example, may be perpendicular to the top surface 101 of the substrate 100.

For example, the second etching gas G2 may include hydrogen chloride (HCl), and the epitaxial material gas G3 may include a silicon (Si) source gas such as dichlorosilane (DCS) and a germanium (Ge) source gas. The ratio of the silicon (Si) source gas to the germanium (Ge) source gas in the epitaxial material gas G3 may be adjusted, so that the concentrations of germanium in the buffer layer 610, the first epitaxial layer 620, the second epitaxial layer 630 and the cap layer 640 may be adjusted accordingly. However, the materials of the buffer layer 610, the first epitaxial layer 620, the second epitaxial layer 630 and the cap layer 640 are only exemplary, and the present disclosure is not limited thereto. The materials of the buffer layer 610, the first epitaxial layer 620, the second epitaxial layer 630 and the cap layer 640 may be adjusted according to actual needs, and the compositions of the second etching gas G2 and the epitaxial material gas G3 may be adjusted accordingly.

In the embodiment, the buffer layer 610 is disposed between the substrate 100 and the first epitaxial layer 620, so that the first epitaxial layer 620 does not contact the substrate 100 directly. With the buffer layer 610, the stress between the substrate 100 and the first epitaxial layer 620 can be reduced. In the embodiment, the top surface (not label) of the first epitaxial layer 620 is aligned or substantially aligned with the top surface 101 of the substrate 100. Herein, the top surface 101 of substrate 100 refers to the uppermost surface of substrate 100 without forming the recesses 520.

In this embodiment, the number of the epitaxial layers (i.e., the first epitaxial layer 620 and the second epitaxial layer 630) at the same side of the gate structure 200 is two. However, it is only exemplary, and the present disclosure is not limited thereto. For example, in other embodiments, the second epitaxial layer 630 shown in FIG. 5 may be replaced by the first epitaxial layer 620. That is, each of the recesses 520 may only be disposed with one epitaxial layer (i.e., the first epitaxial layer 620). The first epitaxial layer 620 is disposed in the recess 520 and protrudes from the top surface 101 of the substrate 100, and the concentration of germanium in the first epitaxial layer 620 is substantially fixed. As another example, the first epitaxial layer 620 shown in FIG. 5 may be replaced by the second epitaxial layer 630 in other embodiment. That is, each of the recesses 520 may only be disposed with one epitaxial layer (i.e., the second epitaxial layer 630). The second epitaxial layer 630 is disposed in the recess 520 and protrudes from the top surface 101 of the substrate 100, and the concentration of germanium in the second epitaxial layer 630 may change in gradient along the vertical direction D2 from bottom to top.

In the present disclosure, the steps shown in FIG. 4 and FIG. 5 may be performed in the same chamber 700. That is, the dry etching process P2 and the selective epitaxial growth process P3 for forming the buffer layers 610, the first epitaxial layers 620, the second epitaxial layers 630 and the cap layers 640 may be performed in the same chamber 700. The aforementioned chamber 700 is preferably the chamber of the apparatus used to perform the selective epitaxial growth process P3. For example, the chamber 700 may be the chamber of the chemical vapor deposition system. In addition, the type of the first etching gas G1 may be the same as the type of the second etching gas G2. Thereby, it is favorable for simplifying the process.

Specifically, a baking step is required before performing the selective epitaxial growth process P3. For example, the semiconductor device shown in FIG. 3 is required to be heated with a temperature ranging from 700° C. to 725° C. for 50 seconds to 70 seconds, so as to remove contaminants on the surface of the semiconductor device. In the present disclosure, by increasing the temperature of the baking step and introducing the first etching gas G1, the initial recess 510 shown in FIG. 3 may be converted into the recess 520. Thereby, the recess 520 includes at least two tip structures, which is more conducive to improve the strain in the lattice close to the channel region compared with the initial recess 510 including the U-shaped profile. Meanwhile, the contaminants on the surface of the semiconductor device can be removed. After the dry etching process P2 is completed, the selective epitaxial growth process P3 can be directly performed in the same chamber 700. It is not necessary to transfer the semiconductor device shown in FIG. 4 into another apparatus, so that the process can be simplified. In addition, the type of the first etching gas G1 may be the same as the type of the second etching gas G2. Thereby, is not necessary to use additional materials and can simplify the types of materials. In other words, in the present disclosure, the dry etching process P2 can be integrated into the baking step before performing the selective epitaxial growth process P3, and can use the existing apparatus and materials of the selective epitaxial growth process P3 without spending additional time (the time for the dry etching process P2 can be the same as the time for the baking step), and the initial recess 510 can be converted into the recess 520. Therefore, the effect of simplifying the process can be provided.

According to the present disclosure, when forming the first epitaxial layers 620, an in-situ implantation process and an annealing process may be performed to implant dopants into the first epitaxial layers 620 to form source/drain regions (not labeled). Alternatively, after the first epitaxial layers 620 are formed, the implantation process and the annealing process are performed to form the source/drain regions in the first epitaxial layers 620. The above two methods to form the source/drain regions are all within the scope of the present disclosure.

Although not shown in the drawings, the method for fabricating the semiconductor device may further include other processes for fabricating transistors. For example, a contact etch stop layer (CESL) and an interlayer dielectric (ILD) layer may be formed in sequence to cover the gate structure 200 and the cap layer 640. A replacement metal gate (RMG) process may be performed to replace the non-metallic conductive material of the gate structure 200 with a single-layer structure or a multi-layer structure including a metallic conductive material. The aforementioned single-layer structure may only include a low-resistance metal layer, and a material of the low-resistance metal layer may include, for example, copper (Cu), aluminum (Al), tungsten (W), titanium aluminum alloy (TiAl), cobalt tungsten phosphide (CoWP) or a combination thereof. The aforementioned multi-layer structure may include low-resistance metal layer, and a high dielectric constant (high-k) dielectric layer and/or a barrier layer and/or a work function metal layer. The replacement metal gate process is well known to those skilled in the art and is omitted herein.

The aforementioned film layers, such as the gate dielectric layer 210, the gate material layer 220, the mask layer 230, the first spacer 310 and the second spacer 320, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

Please refer to FIG. 5, which shows a schematic cross-sectional view of the semiconductor device 1 according to an embodiment of the present disclosure. Herein, the semiconductor device 1 is exemplary a PMOS transistor. The semiconductor device 1 includes the gate structure 200, the two recesses 520 (see FIG. 4) and the two first epitaxial layers 620. The gate structure 200 is disposed on the substrate 100. The two recesses 520 are disposed in the substrate 100 and at the two sides of the gate structure 200. Each of the recesses 520 includes the first inclined surface 521, the second inclined surface 523 and the third inclined surface 525 connected sequentially from bottom to top. The first inclined surface 521 and the second inclined surface 523 define the first tip structure 522 therebetween. The second inclined surface 523 and the third inclined surface 525 define the second tip structure 524 therebetween. The two first epitaxial layers 620 are respectively disposed in the two recesses 520.

The semiconductor device 1 may further optionally include the spacer 300 surrounding the gate structure 200. The semiconductor device 1 may further optionally include the two buffer layers 610 respectively disposed in the two recesses 520, the two second epitaxial layers 630 respectively disposed on the two first epitaxial layers 620 and the two cap layers 640 respectively disposed on the two second epitaxial layers 630.

According to an embodiment of the present disclosure, the number of the first inclined surfaces 521 is two, and the two first inclined surfaces 521 are connected with each other and define the third tip structure 526 therebetween. That is, each recess 520 may include at least three tip structures. The third tip structure 526 may be located at the bottom of the recess 520, and the third tip structure 526 may be located at the center of the recess 520.

According to an embodiment of the present disclosure, the number of the first inclined surfaces 521 may be two, the number of the second inclined surfaces 523 may be two, the number of the third inclined surfaces 525 may be two, and the two first inclined surfaces 521, the two second inclined surfaces 523 and the two third inclined surfaces 525 may be symmetrical to each other. In this case, in each of the recesses 520, the number of the first tip structures 522 is two, the two first tip structures 522 are symmetrical to each other, the number of the second tip structures 524 is two, and the two second tip structures 524 are symmetrical to each other, the third tip structures 526 is disposed between the two first tip structures 522, and the third tip structures 526 is disposed between the two second tip structures 524. As shown in FIG. 4, the two first inclined surfaces 521, the two second inclined surfaces 523, the two third inclined surfaces 526 of each of the recesses 520 and the opening facing upwardly of each of the recesses 520 may together form a heptagon. That is, each of the recesses 520 may include a heptagonal profile.

According to an embodiment of the present disclosure, the first tip structure 522 has a first included angle A1, the second tip structure 524 has a second included angle A2, the third tip structure 526 has a third included angle A3, the first included angle A1 may be greater than the third included angle A3, and the third included angle A3 may be greater than the second included angle A2. According to an embodiment of the present disclosure, the first included angle A1 may be equal to 150.5 degrees, the second included angle A2 may be equal to 109.4 degrees, and the third included angle A3 may be equal to 129.6 degrees.

According to an embodiment of the present disclosure, the substrate 100 may be a silicon substrate. In this case, the substrate 100 may include a silicon-containing layer (i.e., the silicon substrate itself), the two recesses 520 are disposed in the silicon-containing layer, the crystalline orientation of the first inclined surface 521 may be selected from the {311} family of crystalline planes, the crystalline orientation of the second inclined surface 523 may be selected from the {111} family of crystalline planes, and the crystalline orientation of the third inclined surface 525 may be selected from the {111} family of crystalline planes. In the present disclosure, when a crystalline orientation of an inclined surface is selected from a family of crystalline planes, it may refer that the crystalline orientation of the inclined surface may be one of the crystalline planes included in the family. For other details of the semiconductor device 1, references may be made to the above relevant description, and are omitted herein.

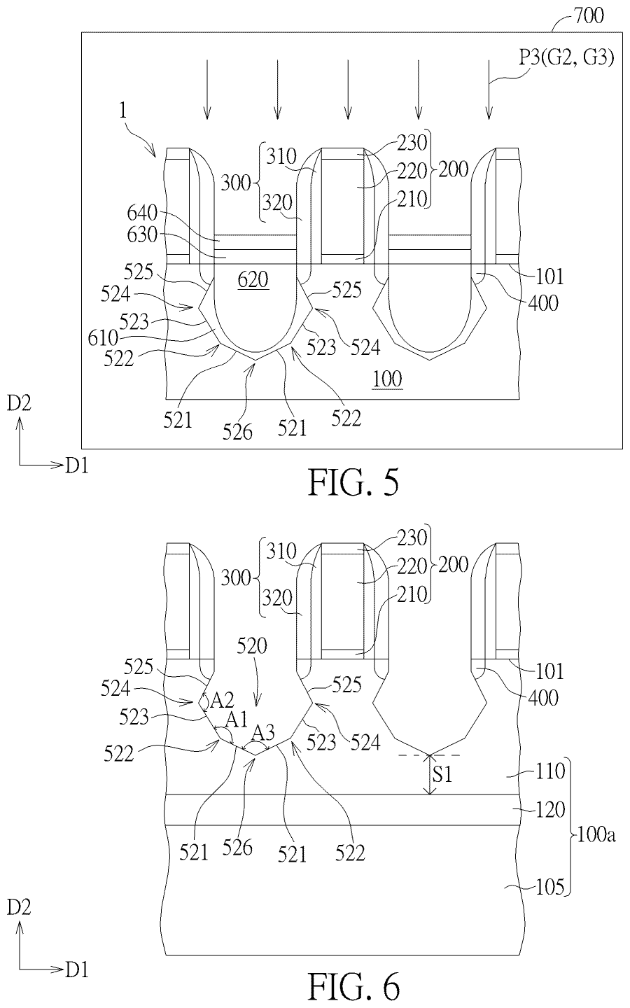

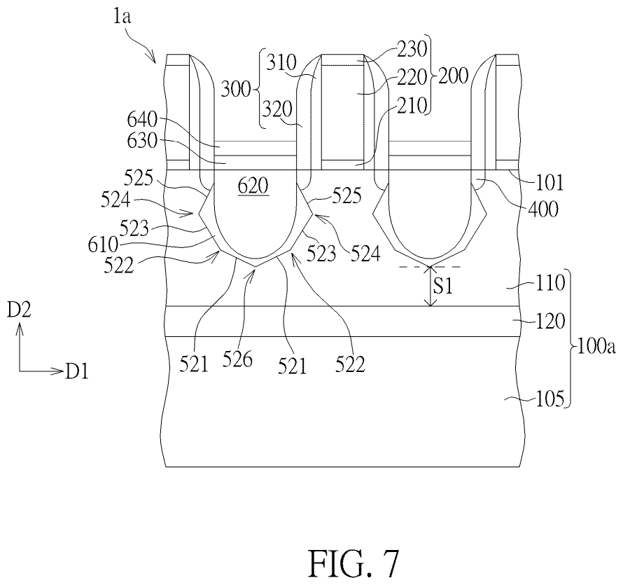

Please refer to FIG. 6 and FIG. 7. FIG. 6 is a schematic cross-sectional view showing a semi-finished semiconductor device according to another embodiment of the present disclosure. FIG. 7 is a schematic cross-sectional view showing a semiconductor device 1a according to the another embodiment of the present disclosure. The semi-finished semiconductor device shown in FIG. 6 has been subjected to the dry etching process P2 (see FIG. 4). The selective epitaxial growth process P3 may be applied to the semi-finished semiconductor device shown in FIG. 6 to obtain the semiconductor device 1a shown in FIG. 7. The main difference between the semiconductor device 1a and the semiconductor device 1 is that the substrate 100a is different from the substrate 100. In FIG. 6 and FIG. 7, the substrate 100a is a silicon on insulator (SOI) substrate, which includes a first silicon-containing layer 105, an insulating layer 120 and a second silicon-containing layer 110 from bottom to top. The first silicon-containing layer 105 and the second silicon-containing layer 110 may be, for example, a silicon layer or an epitaxial silicon layer, and the insulating layer 120 may be, for example, a silicon dioxide layer. The two recesses 520 are disposed in the second silicon-containing layer 110 located above, and the minimum distance S1 between each of the recesses 520 and the insulating layer 120 in the vertical direction D2 is greater than or equal to 50 angstroms (Å) and less than or equal to 100 Å. Thereby, the distance between the recess 520 and the insulating layer 120 is moderate. On the one hand, it is favorable for the recess 520 to form a complete tip structure so as to generate sufficient strain in the lattice of the channel region. On the other hand, it can prevent the recess 520 from penetrating through the second silicon-containing layer 110 located above to expose the insulating layer 120, which results in that the selective epitaxial growth process P3 cannot form epitaxial layer in the recess 520. For other details of the semiconductor device 1a, references may be made to the above relevant description, and are omitted herein.

Compared with the prior art, in the present disclosure, by improving the shape of the recess to allow the recess to include at least two tip structures, it is favorable for generating stress in the lattice close to the channel region, so that the carrier mobility in the channel region can be increased. Preferably, in the present disclosure, the dry etching process for forming the recess can be integrated into the baking step before performing the selective epitaxial growth process, which may further simplified the process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a gate structure disposed on a substrate;
two recesses disposed in the substrate and at two sides of the gate structure, wherein each of the recesses comprises a first inclined surface, a second inclined surface and a third inclined surface connected sequentially from bottom to top, the first inclined surface and the second inclined surface define a first tip structure therebetween, and the second inclined surface and the third inclined surface define a second tip structure therebetween; and
two epitaxial layers respectively disposed in the two recesses.

2. The semiconductor device of claim 1, wherein a number of the first inclined surfaces is two, and the two first inclined surfaces are connected with each other and define a third tip structure therebetween.

3. The semiconductor device of claim 2, wherein the first tip structure has a first included angle, the second tip structure has a second included angle, the third tip structure has a third included angle, the first included angle is greater than the third included angle, and the third included angle is greater than the second included angle.

4. The semiconductor device of claim 3, wherein the first included angle is equal to 150.5 degrees, the second included angle is equal to 109.4 degrees, and the third included angle is equal to 129.6 degrees.

5. The semiconductor device of claim 1, wherein the substrate comprises a silicon-containing layer, the two recesses are disposed in the silicon-containing layer, and a crystalline orientation of the first inclined surface is selected from a {311} family of crystalline planes.

6. The semiconductor device of claim 1, wherein the substrate comprises a silicon-containing layer, the two recesses are disposed in the silicon-containing layer, and a crystalline orientation of the second inclined surface is selected from a {111} family of crystalline planes.

7. The semiconductor device of claim 1, wherein the substrate comprises a silicon-containing layer, the two recesses are disposed in the silicon-containing layer, and a crystalline orientation of the third inclined surface is selected from a {111} family of crystalline planes.

8. The semiconductor device of claim 1, wherein a number of the first inclined surfaces is two, a number of the second inclined surfaces is two, a number of the third inclined surfaces is two, and the two first inclined surfaces, the two second inclined surfaces and the two third inclined surfaces are symmetrical to each other.

9. The semiconductor device of claim 1, wherein each of the recesses comprises a heptagonal profile.

10. The semiconductor device of claim 1, wherein the substrate comprises an insulating layer and a silicon-containing layer disposed on the insulating layer, the two recesses are disposed in the silicon-containing layer, and a minimum distance between each of the recesses and the insulating layer in a vertical direction is greater than or equal to 50 Å and less than or equal to 100 Å.

11. A method for fabricating a semiconductor device, comprising:
forming a gate structure on a substrate;
forming two recesses in the substrate and at two sides of the gate structure, wherein each of the recesses comprises a first inclined surface, a second inclined surface and a third inclined surface connected sequentially from bottom to top, the first inclined surface and the second inclined surface define a first tip structure therebetween, and the second inclined surface and the third inclined surface define a second tip structure therebetween; and
forming two epitaxial layers respectively in the two recesses.

12. The method of claim 11, wherein a number of the first inclined surfaces is two, and the two first inclined surfaces are connected with each other and define a third tip structure therebetween.

13. The method of claim 11, wherein forming the two recesses in
the substrate and at the two sides of the gate structure comprises:
forming two initial recesses in the substrate and at the two sides of the gate structure, wherein each of the initial recesses comprises a U-shaped profile; and
performing a dry etching process to convert the two initial recesses into the two recesses.

14. The method of claim 13, wherein the dry etching process is performed at a temperature ranging from 800 °C to 900 °C.

15. The method of claim 13, wherein the dry etching process is performed for 50 seconds to 70 seconds.

16. The method of claim 13, wherein performing the dry etching process comprises introducing a first etching gas.

17. The method of claim 16, wherein the first etching gas comprises hydrogen chloride, and a flow rate of the first etching gas ranges from 50 sccm to 250 sccm.

18. The method of claim 16, wherein forming the two epitaxial layers in the two recesses comprises introducing a second etching gas and an epitaxial material gas, and a type of the second etching gas is the same as a type of the first etching gas.

19. The method of claim 13, wherein the dry etching process and forming the two epitaxial layers are performed in a same chamber.

20. The method of claim 11, wherein the substrate comprises an insulating layer and a silicon-containing layer disposed on the insulating layer, the two recesses are disposed in the silicon-containing layer, and a minimum distance between each of the recesses and the insulating layer in a vertical direction is greater than or equal to 50 Å and less than or equal to 100 Å.
